(19) United States
(12) Patent Application Publication
(10) Pub. No.: US 2012/0316803 A1
(43) Pub. Date: Dec. 13, 2012

(54) SEMICONDUCTOR TEST DATA ANALYSIS SYSTEM

(75) Inventors: Paul SIMON, Villevielle (FR); Dirk Kenneth DE VRIES, Saint Georges D'Orques (FR); Thierry RAYMOND, Grabels (FR)

(73) Assignee: QUALTERA, Montpellier (FR)

(21) Appl. No.: 13/488,758

(22) Filed: Jun. 5, 2012

(30) Foreign Application Priority Data
Jun. 6, 2011 (FR) 11/54877

(51) Int. Cl. G06F 17/18; G01R 31/26

(52) U.S. Cl. 702/58

(57) ABSTRACT

The invention concerns a system for processing semi-conductor test data relating to a plurality of dies formed by a manufacturing process on at least one silicon wafer, the system comprising: an input arranged to receive said semiconductor test data (202); one or more memories (226, 242) adapted to store a database comprising said semiconductor test data and a plurality of test data patterns, wherein each of said test data patterns is associated with a corresponding output data value indicating an associated recommendation for modifying said manufacturing process; and at least one processing unit (232) configured to analyse the values of said semiconductor test data, and/or values derived from said semiconductor test data, to identify a match with at least one of said test data patterns, and to output the corresponding output data value indicating the associated recommendation.

### FIELD OF THE INVENTION

The present invention relates to a system and method for processing semiconductor test data.

### BACKGROUND OF THE INVENTION

During the manufacture of integrated circuits, a silicon wafer is divided into a number of dies, each of which corresponds to a rectangular silicon substrate on which a chip is formed. In particular, the wafer is subject to semiconductor processing steps, such as photolithography, etching, doping, and the deposition of various materials, to form each chip of each die. Then, the wafer is diced to separate the individual chips, which are in turn packaged to form integrated circuits.

During and following the manufacturing process, various tests of dies of the wafer are performed, which may include electrical wafer sort tests and electrical tests of the integrated circuit, also referred to herein as “final tests”. The aim of such tests is to reject the dies that are faulty, and/or that do not meet certain criteria.

The number of faulty dies per wafer has a direct impact on the elementary cost of each functional integrated circuit exiting the factory. There is thus a desire in the industry to trace the causes behind high rejection rates of dies in the silicon wafer, and correct the manufacturing process where possible. Indeed, generally when a die is rejected, the circumstances of the rejection are logged by classifying each die as falling in a certain “test bin”. This information is included in the test data associated with each wafer.

The analysis of the wafer sort and final test data is generally performed manually by a specialized analyst, who attempts to make inferences regarding the causes of the rejection of certain dies based on the test data. This analysis process is time consuming. This is undesirable, given that the longer the delay before action is taken to correct the manufacturing process, the more dies will be rejected in the meantime. Furthermore, the analysis process is inefficient and irregular, given that any single analyst does not necessarily benefit from the experiences of fellow analysts and that it relies on human judgement, which may vary from one analyst to another, and is subject to error.

It would therefore be desirable to automate to some extent the analysis process, but there exist technical difficulties in doing so.

### SUMMARY OF THE INVENTION

It is an aim of embodiments of the present invention to at least partially address one or more difficulties in the prior art.

According to one aspect of the present invention, there is provided a system for processing semiconductor test data relating to a plurality of dies formed by a manufacturing process on at least one silicon wafer, the system comprising: an input arranged to receive said semiconductor test data; one or more memories adapted to store a database comprising said semiconductor test data and a plurality of test data patterns, wherein each of said test data patterns is associated with a corresponding output data value indicating an associated recommendation for modifying said manufacturing process; and at least one processing unit configured to analyse the values of said semiconductor test data, and/or values derived from said semiconductor test data, to identify a match with at least one of said test data patterns, and to output the corresponding output data value indicating the associated recommendation.

According to one embodiment, one or more of said plurality of test data patterns comprises an algorithm, and wherein said at least one processing unit is configured to execute said algorithm to identify the match with at least one of said test data patterns.

According to another embodiment, one or more of said plurality of test data patterns defines a range of a plurality of values of or derived from said semiconductor test data.

According to another embodiment, the system further comprises at least one input adapted to receive a user response to said output data value, wherein said at least one processing unit is further configured to adapt said output data value based on said user response.

According to another embodiment, said at least one processing unit is further configured to adapt at least one of said plurality of test data patterns based on said user response.

According to another embodiment, said at least one processing unit is further adapted to generate test data statistics based on said semiconductor test data, and further comprising a web interface configured to present said test data statistics on a web page.

According to another embodiment, the at least one processing unit is configured to analyse said test data statistics to identify said match with at least one of said test data patterns.

According to another embodiment, the system further comprises data source equipment adapted to supply said semiconductor test data.

According to another embodiment, said data source equipment comprises semiconductor test equipment adapted to test the dies of a silicon wafer prior to dicing of the silicon wafer, and product test equipment adapted to test the integrated circuits produced from the dies of a silicon wafer.

According to a further aspect of the present invention, there is provided a method of processing semiconductor test data relating to a plurality of dies formed by a manufacturing process on at least one silicon wafer, the method comprising: receiving said semiconductor test data and storing said semiconductor test data in a database; analysing values of said semiconductor test data, and/or values derived from said semiconductor test data, to identify a match with one or more of a plurality of test data patterns, each of said test data patterns being associated with a corresponding output data value indicating an associated recommendation for modifying said manufacturing process; and based on the identified one or more matches, outputting the corresponding output data value indicating the associated recommendation.

### BRIEF DESCRIPTION OF THE DRAWINGS

The foregoing and other purposes, features, aspects and advantages of the invention will become apparent from the following detailed description of embodiments, given by way of illustration and not limitation with reference to the accompanying drawings, in which:

FIG. 1 illustrates a silicon wafer according to one example;

FIG. 2 illustrates a system for processing semiconductor test data according to an embodiment of the present invention;

FIGS. 3A and 3B are flow diagrams illustrating steps in a method of processing semiconductor test data according to embodiments of the present invention;

FIG. 4 illustrates schematically a device for processing data according to an embodiment of the present invention; and

FIG. 5 illustrates a memory structure storing graphical representations of test data statistics according to an embodiment of the present invention.

### DETAILED DESCRIPTION OF EMBODIMENTS OF THE INVENTION

Only those aspects useful for an understanding of the present disclosure have been described in detail herein and illustrated in the drawings. Other aspects, such as the particular tests used to generate the semiconductor test data, comprising for example wafer sort and/or final test data, have not been described in detail, it being evident to those skilled in the art that the teaching of the present disclosure could be applied to the semiconductor test data resulting from a wide range of tests.

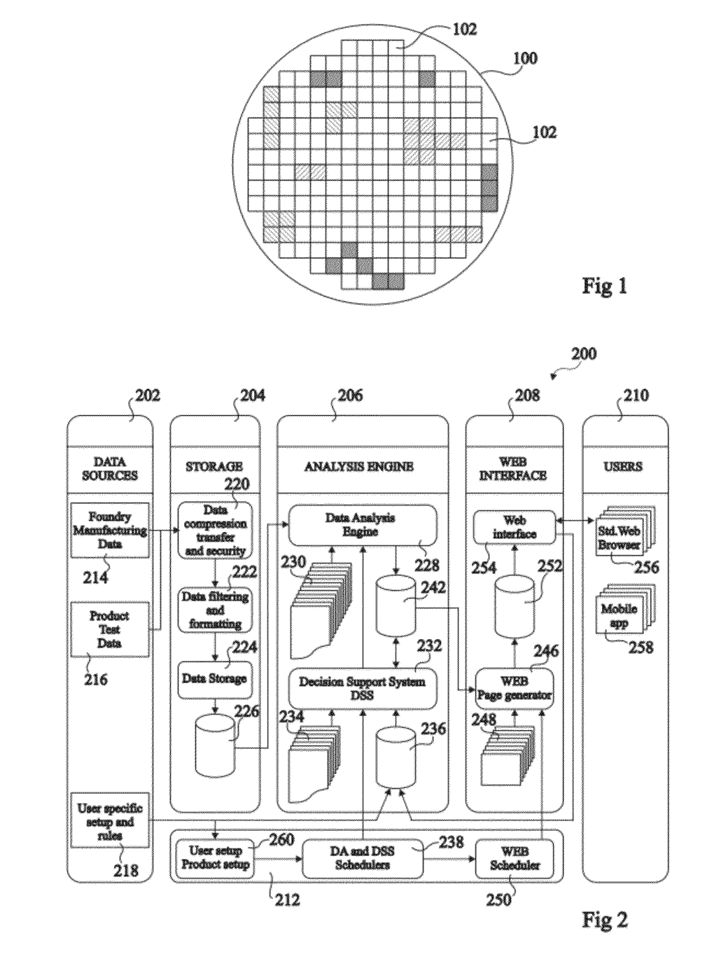

FIG. 1 schematically illustrates, in plan view, an example of a silicon wafer 100 and represents an example of the information forming the wafer sort test data according to some embodiments described herein.

The wafer 100, which is in the form of a substantially circular silicon disk, comprises an array of rectangular dies 102, each of which corresponds to an integrated circuit. As explained above, during and following the manufacturing process, various tests of dies of the wafer are performed, which may include wafer probe tests, electrical wafer sort tests, and electrical tests of the integrated circuit. One or more of the dies may be found to be faulty, and classified as falling in one of a number of “test bins”, based on the identified fault. In the example of FIG. 1, the dies represented as hollow squares have passed the test run, whereas the dies represented by solid squares or diagonally shaded squares have failed the test run for any of a number of reasons.

For example, the solid squares represent dies that failed due to scratches on the surface of the wafer, the squares with diagonal stripes going from bottom left to top right represent dies that failed due to errors detected during the test run or during fabrication, and the squares with diagonal stripes going from the bottom right to top left represent dies that failed predefined power consumption limits for the part.

Thus, in one example, the semiconductor test data corresponds to the data resulting from the test run of each wafer, and comprises the total number of failed dies on each wafer, the number of failed dies in each category and/or the locations of the failed dies on each wafer, for example provided as x,y co-ordinates. The data can also include the number of dies assigned to a specific “test bin”. Furthermore, the data may include statistics on parametric data captured during the testing process, such as wafer level mean or median values of the maximum operating frequency (FMAX), the standby power consumption, and/or other analog parameters such as Total Harmonic Distortion (THD).

FIG. 2 schematically illustrates an overview of a system 200 for processing semiconductor test data according to one embodiment.

A number of data sources 202 provide semiconductor test data to a storage module 204, which maintains a database of semiconductor test data. The semiconductor test data is then analysed by an analysis engine 206, which in turn communicates with a web interface module 208, allowing the analysis results to be made available to user equipment 210. Furthermore, a control module 212 controls aspects of the analysis engine 206 and web interface module 208 as will be described in more detail below.

The data sources 202 include foundry manufacturing data 214, which is semiconductor test data originating from manufacturing factories. This data comprises parameter measurements of the wafers, for example parametric data gathered on scribe lane test structures, comprising for example PCM (process control module) data and/or WAT (wafer acceptance test) data. The data sources 202 also include product test data 216, which is test data resulting from a functional test of the integrated circuit, and this data for example originates from specific test sites. The product test data is for example in the STDF (Standard Test Data Format) format, although other formats may be supported. Data sources may also include user specific setup data and rules 218, described in more detail below.

The storage module 204 for example comprises a data compression transfer and security unit 220, which receives the semiconductor test data 214, 216, and deals with compression and/or security protocols that have been applied to the data, for example by performing decompression and/or decryption on the semiconductor test data.

The test data from unit 220 is provided to a data filtering and formatting unit 222, which for example filters out test data that is irrelevant for the purposes of system 200 as well as data of which the integrity can not be guaranteed, and standardizes the data format, for example by converting the test data into a specific format.

The filtered semiconductor test data from unit 222 is provided to a data storage unit 224, which stores the data in a database 226, ready for analysis.

The analysis engine 206 for example comprises a data analysis engine 228, which retrieves the semiconductor test data from the database 226, and analyses it based on a set of algorithms and analysis rules 230. These algorithms and rules 230 for example define how the data is to be processed in order to generate test data statistics indicating a trend of one or more indicators extracted and/or derived from the test data. The test data statistics for example illustrate an evolution of the indicators in time or across a number of wafers. As one example, the test data could show the fluctuations over a week in the percentage of dies of each wafer or each lot of wafers that have passed all of the tests. Obviously, there are many different types of indicators that could be derived from the semiconductor test data.

The data analysis engine 206 also receives an input from a decision support system 232, which in turn uses memorized methods and algorithms 234, and acquired knowledge stored in a storage element 236. The methods and algorithms 234 allow certain data patterns and correlations in the semiconductor test data and/or in the test data statistics to be identified. The decision support can be based on the test data directly, on data derived from it, and/or on the additional analysis based on test data patterns and correlations, for example executing a multi-step analysis flow that takes, at each step, some or all of the previously obtained results, and generates new data and/or data patterns based on the previously obtained results. The data patterns define a combination of certain features in the semiconductor test data or in the test data statistics derived from the semiconductor test data, such as values in certain ranges, or a particular spatial distribution of faulty dies. As a further example, sudden dips or peaks in certain test data statistics, such as the percentage of faulty dies, in combination with certain variations in the test parameters, may be automatically recognized as indicating a certain problem in the manufacturing process.

The decision support system 232 is controlled by a data analysis and data decision support system scheduler 238 of the control circuitry 212, which controls when the decision support system 232 is activated. The data analysis engine 228 provides output data, comprising the test data statistics and the semiconductor test data to a storage component 242. The storage component 242 is also accessible by the decision support system 232, which applies the methods and algorithms 234 to the test data and test data statistics in order to detect the data patterns in the data stored by component 242. Each data pattern defined by the methods and algorithms 234 is associated with a corresponding recommendation for modifying the manufacturing or testing process. The decision support system 232 thereby generates, based on the detected data patterns, one or more output data values indicating an associated recommendation for modifying the manufacturing or testing process. This output data is for example stored in the storage component 242.

The data from the storage component 242 is provided to web page generator 246, which uses the results from the data analysis engine 228 to generate graphics that may be provided in web page format. Furthermore, it presents the available recommendations in a format readable by a user. For example, the web page generator 246 may receive templates 248, based on which the test data statistics and recommendations are displayed. The web page generator 246 is for example controlled by web scheduler 250 of the control circuitry 212, which controls when new web data is generated. The web data, formed of the graphics and recommendations, is then stored in a memory component 252, from where it may be accessible by a user in response to a request made via a web interface unit 254.

The web interface unit 254 is accessible, for example via the internet, by the standard web browser 256 of a user PC (personal computer), and/or by a mobile application 258 of a mobile communications device. The same system 200 may make different data available to different users. For example, one user may wish to monitor wafer production relating to their product of a processor chip for a laptop computer, while another user may wish to monitor wafer production relating to their product of an integrated circuit for a mobile telephone. Each user may have access to only the test data statistics and recommendations concerning their product, and this restricted access is for example controlled by password protected partitions in the storage device 252.

The web interface 254 also provides user feedback data to the acquired knowledge database 236. This data enables new patterns in the test data to be identified, such that the systems learns and is able to make new types of recommendations based on this knowledge. Also, user rules 218 may provide further criteria for determining the test data patterns.

Additionally, the control circuitry 212 comprises a user setup and product setup unit 260, which defines user and product parameters, such as user access rights to certain product data, and physical, logistical and design data related to the products.

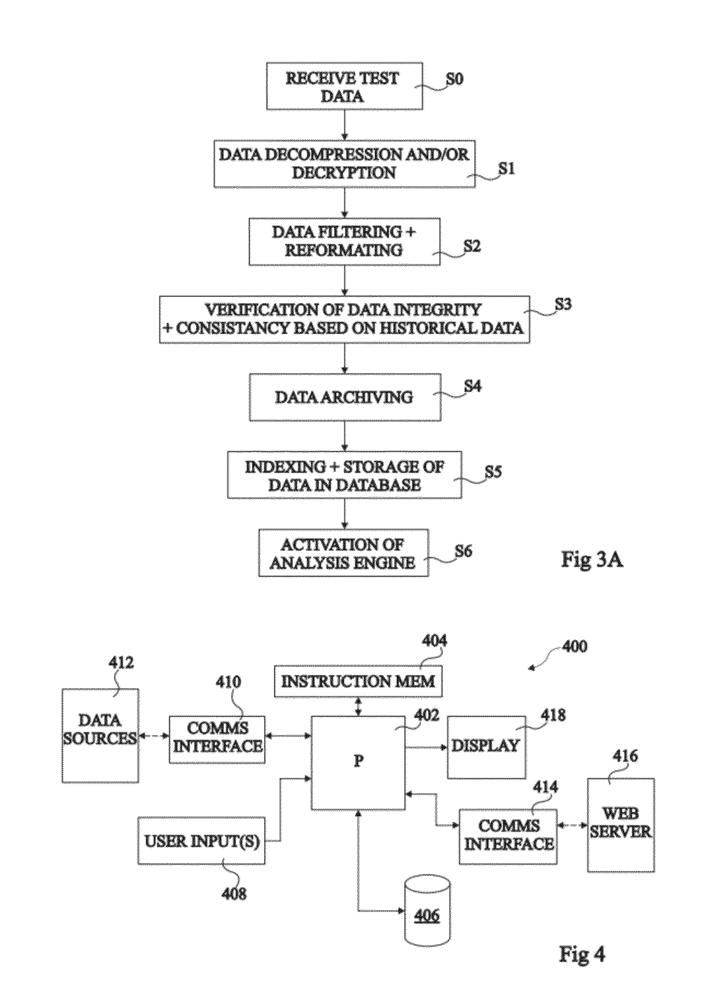

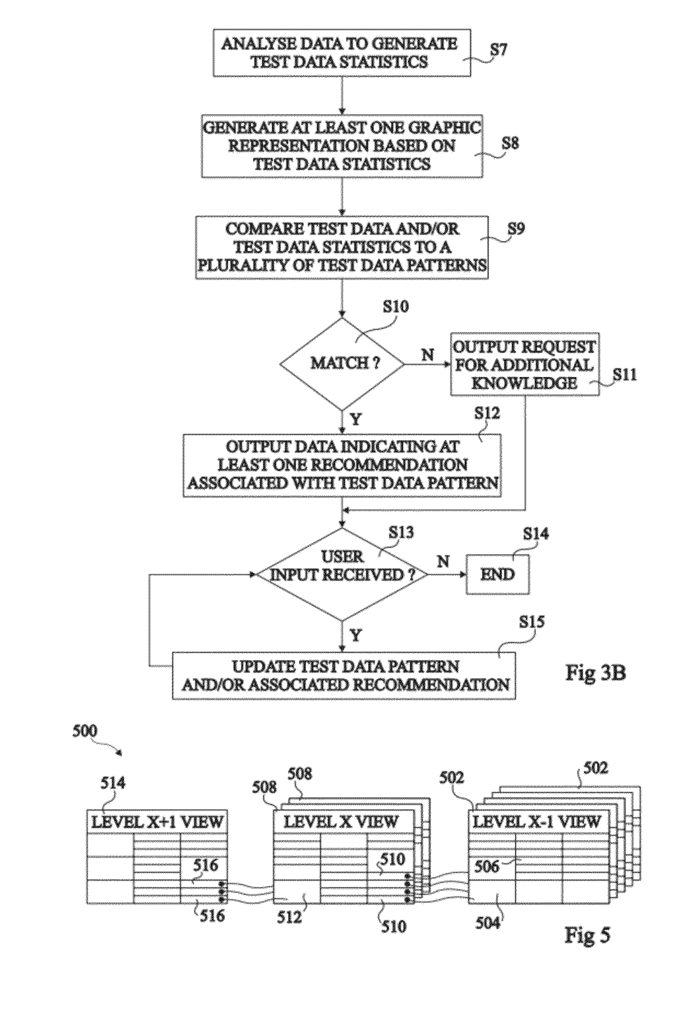

Operation of the system 200 of FIG. 2 will now be described in more detail with reference to the flow diagrams of FIGS. 3A and 3B.

With reference to FIG. 3A, in a first step S0, new semiconductor test data is received by the data source module 202 of FIG. 2.

In a next step S1, data decompression and/or decryption is performed by block 220. For example, in the case that the data is transmitted via the internet to the storage module 204, encryption may be used to provide security against third parties obtaining access to the data. Additionally, compression may used to reduce the size of the files that are transmitted, and thus reduce transmission bandwidth requirements.

In a next step S2, data filtering and reformatting is performed, which, as described above, may involve removing irrelevant test data, and reformatting the data into a specific standardized format.

In a next step S3, a verification of data integrity and consistency is performed, for example based on historical data. This for example involves verifying that the data is in expected ranges, and that data is present for all of the dies on a wafer.

In a next step S4, data archiving is optionally performed, which for example involves backing-up the filtered and formatted data in long term storage.

In a next step S5, the data is entered into the database 226, and the data is indexed, such that it can be accessed by the analysis engine 206 of FIG. 2 in subsequent steps.

In a step S6, the analysis engine 206 is activated, for example by the scheduler 238 of FIG. 2.

With reference to FIG. 3B, an example of the steps then performed by the analysis engine 206 will now be described.

In a step S7, the semiconductor test data is analysed to generate test data statistics, for example by extracting or deriving certain indicators from the semiconductor test data as determined above, based on the algorithms and rules 230.

In a next step S8, the test data statistics are transformed into graphical representations, such that they may be displayed to a user via a web interface.

In a next step S9, the decision support system 232 of FIG. 2 compares the semiconductor test data and/or the test data statistics with a plurality of test data patterns. As described above, such a comparison may be performed by executing an algorithm, which processes the semiconductor test data and/or test data statistics and provides an indication of a match with one or more of the test data patterns.

In a next step S10, it is determined whether there has been a match between the test data/statistics and one or more of the test data patterns. If not, the next step is S11, in which the user is requested to provide additional knowledge to the system, indicating any conclusions that may be drawn from the test data. Alternatively, if one or more matches occur, the next step is S12.

In S12, output data is generated that indicates at least one recommendation associated with the identified test data patterns. The recommendation indicates how the manufacturing process may be corrected and thus improved.

After step S11 or S12, the next step is S13, in which it is determined whether or not a user input has been received. In particular, in step S12, the recommendation is provided via the web interface to one or more users, who may disagree with the recommendation, or have additional suggestions for conclusions that may be drawn from the data. In such a case, the user may submit alternative/additional diagnostics, and corresponding recommendations.

If no such user input is received in step S13, the next step is S14, in which the process ends until new test data is received. Alternatively, if a user input is received, the next step is S15, in which the user feedback is used to adapt at least one of the recommendations and/or add one or more new algorithms in the knowledge database 236. After S15, the method returns to step S13, giving the user a further opportunity to provide feedback based on the adapted recommendations.

FIG. 4 illustrates a device 400, which may be configured to implement the method as described herein.

The device 400 comprises a processing unit P 402, which may be a multi-core processor, and is for example controlled by an instruction memory 404. In particular, the instruction memory 404 for example stores groups of instructions that cause the processing unit 402 to implement the steps of FIGS. 3A and 3B.

The processing unit 402 is also in communication with memory storage 406, which may comprise one or more volatile or non-volatile memory devices storing the semiconductor test data, test data statistics, web pages and acquired knowledge, thereby implementing the storage components 224, 236, 242 and 252 of FIG. 2.

One or more user inputs 408 are provided to the processing unit 402, which could include a keyboard and a mouse, and for example correspond to the control inputs of an administrator.

A communications interface 410 is for example coupled to the processing unit 402, and allows the input data from the data sources 412 to be received, for example via a network such as the internet. Furthermore, a communications interface 414 may be coupled to the processing unit 402 for communicating with a web server 416, on which the web pages displaying the test data statistics and recommendations may be hosted.

A display 418 is for example present, for allowing a system administrator to modify the system.

While one device 400 is illustrated for implementing the various portions of the system 200 of FIG. 2, in alternative embodiments, one or more of the modules 202, 204, 206, 208 and 212 may be implemented by different devices similar to device 400 in communication with each other.

FIG. 5 illustrates a memory structure 500, maintained for example in the memory 242 and/or 252 of FIG. 2, and storing the data used for generating the graphic representations of the test data statistics.

As illustrated in FIG. 5, the memory structure for example comprises a plurality of level X-1 views 502. Level X-1 for example corresponds to a wafer level view of the test data statistics, and each view 502 comprises certain data fields 504, 506, for example indicating elements of the test data such as the percentage of successful dies, the number of dies falling in a certain bin, etc.

The memory structure also comprises a plurality of level X views 508. Level X for example corresponds to a lot level view, indicating test data statistics relevant to a particular lot of, for example, 20 wafers. In the level X view, data present in the X-1 views 502 may “bubble-up” and be reproduced. For example, fields 510 of the level X view for example reproduce a test data statistical value 504 of each or some of the level X-1 views. As one particular example, each wafer level view 502 may include a field indicating the yield loss, and the lot level view may indicate any extraordinary yield loss patterns or statistically relevant parametric shifts in the wafers forming the lot. The level X view also for example includes fields storing other statistical data, such as a field 512, which for example indicates the number of wafers in the lot that has more than a certain percentage of successful dies. The memory structure 500 also comprises a level X+1 view 514, which is for example a view showing the yield trend for a series of lots. Again, data from the level below, in this case the level X view, may bubble up to the X+1 level view, and in this example a field 516 for example reproduces the data field 512 for at least some of the lot level views 508. For example, this data field comprises text indicating a possible explanation for a high yield loss for each lot, and a corresponding recommendation.

Thus, the views of each of the levels X-1, X and X+1 in FIG. 5 may all be based on raw test data, and additionally they may summarize data generated by the lower level views, if this data is determined to be of relevance at the higher level.

An advantage of the embodiments described herein is that, by detecting the presence of one or a plurality of test data patterns in the values of semiconductor test data or values derived therefrom, the test data patterns each being associated with a corresponding recommendation, the recommendations for improving a manufacturing process can be generated in a quick and efficient manner.

Having thus described at least one illustrative embodiment of the invention, various alterations, modifications and improvements will readily occur to those skilled in the art.

For example, it will be apparent that the embodiments describe here may be implemented by any combination of hardware and/or software. Furthermore, the various features described in relation to the various embodiments could be combined in any combination in alternative embodiments.

1. A system for processing semiconductor test data relating to a plurality of dies formed by a manufacturing process on at least one silicon wafer, the system comprising:
an input arranged to receive said semiconductor test data (202);
one or more memories (226, 242) adapted to store a database comprising said semiconductor test data and a plurality of test data patterns, wherein each of said test data patterns is associated with a corresponding output data value indicating an associated recommendation for modifying said manufacturing process; and
at least one processing unit (232) configured to analyse the values of said semiconductor test data, and/or values derived from said semiconductor test data, to identify a match with at least one of said test data patterns, and to output the corresponding output data value indicating the associated recommendation.

2. The system of claim 1, wherein one or more of said plurality of test data patterns comprises an algorithm, and wherein said at least one processing unit is configured to execute said algorithm to identify the match with at least one of said test data patterns.

3. The system of claim 1, wherein one or more of said plurality of test data patterns defines a range of a plurality of values of or derived from said semiconductor test data.

4. The system of claim 1, further comprising at least one input adapted to receive a user response to said output data value, wherein said at least one processing unit (232) is further configured to adapt said output data value based on said user response.

5. The system of claim 4, wherein said at least one processing unit (232) is further configured to adapt at least one of said plurality of test data patterns based on said user response.

6. The system of claim 1, wherein said at least one processing unit (228) is further adapted to generate test data statistics based on said semiconductor test data, and further comprising a web interface (208) configured to present said test data statistics on a web page.

7. The system of claim 6, wherein the at least one processing unit (232) is configured to analyse said test data statistics to identify said match with at least one of said test data patterns.

8. The system of claim 1, further comprising data source equipment adapted to supply said semiconductor test data.

9. The system of claim 8, wherein said data source equipment comprises semiconductor test equipment adapted to test the dies of a silicon wafer prior to dicing of the silicon wafer, and product test equipment adapted to test the integrated circuits produced from the dies of a silicon wafer.

10. A method of processing semiconductor test data relating to a plurality of dies formed by a manufacturing process on at least one silicon wafer, the method comprising:
receiving said semiconductor test data and storing said semiconductor test data in a database (226);
analysing values of said semiconductor test data, and/or values derived from said semiconductor test data, to identify a match with one or more of a plurality of test data patterns, each of said test data patterns being associated with a corresponding output data value indicating an associated recommendation for modifying said manufacturing process; and
based on the identified one or more matches, outputting the corresponding output data value indicating the associated recommendation.
